(19) United States
(12) Patent Application Publication
(10) Pub. No.: US 2013/0267629 A1
(43) Pub. Date: Oct. 10, 2013

(54) MESOPOROUS SILICA PARTICLES, METHOD FOR PRODUCING MESOPOROUS SILICA PARTICLES, AND MESOPOROUS SILICA PARTICLE-CONTAINING MOLDED ARTICLE

(71) Applicants: Ayumu Fukuoka, Osaka (JP); Hiroki Yabe, Osaka (JP); Tatsuya Okubo, Tokyo (JP); Atsushi Shimojima, Tokyo (JP); Hirotaka Ishii, Tokyo (JP)

(72) Inventors: Ayumu Fukuoka, Osaka (JP); Hiroki Yabe, Osaka (JP); Tatsuya Okubo, Tokyo (JP); Atsushi Shimojima, Tokyo (JP); Hirotaka Ishii, Tokyo (JP)

(73) Assignees: THE UNIVERSITY OF TOKYO, Tokyo (JP); PANASONIC CORPORATION, Osaka (JP)

(21) Appl. No.: 13/995,251

(22) PCT Filed: Dec. 22, 2011
(86) PCT No.: PCT/JP2011/079773

§ 371 Date: Jun. 18, 2013

(30) Foreign Application Priority Data
Feb. 21, 2011 (JP) 2011-035160

(51) Int. Cl. C08K 9/10

(52) U.S. Cl. CPC C08K 9/10
USPC 523/218; 428/404; 427/215

(57) ABSTRACT

The mesoporous silica particles each comprise a core particle comprising first mesopores, wherein a periphery of the core particle is covered with silica. Preferably, second mesopores, smaller than the first mesopores, are provided in the silica-covered part formed by the silica covering. The mesoporous silica particles are produced by: a surfactant complex silica particle preparation step of mixing a surfactant, water, an alkali, a hydrophobic part-containing additive and a silica source to thereby prepare surfactant complex silica particles, said hydrophobic part-containing additive including a hydrophobic part for increasing a volume of micelles to be formed by the surfactant; and a silica covering step of adding the silica source to the surfactant complex silica particles to thereby cover a periphery of each core particle with silica.

### TECHNICAL FIELD

The present invention relates to mesoporous silica particles, a method for producing the mesoporous silica particles, and a molded article obtained using the mesoporous silica particles.

### BACKGROUND ART

Conventionally, silica particles with a hollow structure such as that shown in Patent Literature 1 have been known as particles providing low refractive index (Low-n) and low dielectric constant (Low-k). Recently, there has been demand for greater void ratios in order to achieve higher performance. However, it is difficult to reduce the thickness of the outer shell in hollow silica particles, and the void ratio is likely to decline for structural reasons if the particle size is reduced to 100 nm or less.

Under these circumstances, because the void ratios of mesoporous silica particles are unlikely to decline for structural reasons as the particle size is reduced, they hold promise as next-generation high-void-ratio particles for applications in low refractive index (Low-n), low-dielectric constant (Low-k) materials and materials with low thermal conductivity. A molded article having these functions can also be obtained by dispersing mesoporous silica particles in a resin or other matrix-forming materials (see Patent Literatures 2 to 6).

In order to prepare a molded article having the superior functions of mesoporous silica particles, the high-void-ratio mesoporous silica particles must be supported in the molded article. However, the void volume is too low in conventional mesoporous silica particles, so that if the mesoporous silica content is low, the functions described above cannot be obtained in a molded article, while if the mesoporous silica content is high, the strength of the molded article is diminished. There have been attempts to increase the void ratios of mesoporous silica particles. For example, in Non Patent Literature 1, the mesopores are enlarged by the addition of styrene or the like, increasing the void ratio of the particles. However, in this method, the shape and arrangement of the mesopores are irregular, and the strength of the molded article may be reduced for reasons having to do with the strength of the particles. At the same time, a matrix material is likely to penetrate into the mesopores by the enlargement of the mesopores, and functions such as low refractive index (Low-n), low dielectric constant (Low-k) and low thermal conductivity may be unlikely to be achieved.

### CITATION LIST

### Patent Literature

Patent Literature 1: Japanese Patent Application Laid-open No. 2001-233611
Patent Literature 2: Japanese Patent Application Laid-open No. 2009-040965
Patent Literature 3: Japanese Patent Application Laid-open No. 2009-040966
Patent Literature 4: Japanese Patent Application Laid-open No. 2009-040967
Patent Literature 5: Japanese Patent Application Laid-open No. 2004-083307
Patent Literature 6: Japanese Patent Application Laid-open No. 2007-161518

### Non Patent Literature

Non Patent Literature 1: Microporous and Mesoporous Materials 120 (2009) 447-453

### SUMMARY OF INVENTION

### Technical Problem

The present invention has been made in light of these problems, and it is an object of the present invention to provide mesoporous silica particles which have superior functions such as low refractive index (Low-n), low dielectric constant (Low-k) and low thermal conductivity and also can realize greater strength to a molded article. It is also an object of the present invention to provide a method for producing mesoporous silica particles and a molded article containing these mesoporous silica particles.

### Solution to Problem

Mesoporous silica particles according to the present invention each comprise a core particle comprising first mesopores, wherein a periphery of the core particle is covered with silica.

In the mesoporous silica particles, second mesopores, smaller than the first mesopores, are preferably provided in a silica-covered part formed by the silica covering.

A method for producing mesoporous silica particles according to the present invention comprises: a surfactant complex silica particle preparation step of mixing a surfactant, water, an alkali, a hydrophobic part-containing additive and a silica source to thereby prepare surfactant complex silica particles, said hydrophobic part-containing additive including a hydrophobic part for increasing a volume of micelles to be formed by the surfactant; and a silica covering step of adding the silica source to the surfactant complex silica particles to thereby cover a periphery of each core particle with silica.

In the method for producing mesoporous silica particles, the silica covering step preferably comprises adding the silica source and the surfactant to thereby cover the surface with silica complexed with the surfactant.

A mesoporous silica particle-containing molded article according to the present invention comprises the mesoporous silica particles in a matrix-forming material.

### Advantageous Effects of Invention

The present invention can provide mesoporous silica particles which can inhibit the penetration of a matrix material into mesopores, and which have superior functions such as low refractive index (Low-n), low dielectric constant (Low-k) and low thermal conductivity and also can impart greater strength to a molded article.

### BRIEF DESCRIPTION OF DRAWINGS

FIG. 1 is a sectional view showing an example of organic EL elements.

FIG. 2A is a graph showing the results of nitrogen adsorption measurement of the mesoporous silica particles of Example 1 as a graph of the adsorption isotherm.

FIG. 2B is a graph showing the results of nitrogen adsorption measurement of the mesoporous silica particles of Example 1 as a graph of the pore diameter distribution.

FIG. 3A is a graph showing the results of nitrogen adsorption measurement of the mesoporous silica particles of Example 2 as a graph of the adsorption isotherm.

FIG. 3B is a graph showing the results of nitrogen adsorption measurement of the mesoporous silica particles of Example 2 as a graph of the pore diameter distribution.

FIG. 4A is a graph showing the results of nitrogen adsorption measurement of the mesoporous silica particles of Comparative Example 1 as a graph of the adsorption isotherm.

FIG. 4B is a graph showing the results of nitrogen adsorption measurement of the mesoporous silica particles of Comparative Example 1 as a graph of the pore diameter distribution.

FIG. 5A is a graph showing the results of X-ray diffraction measurement of the mesoporous silica particles obtained in Examples 1.

FIG. 5B is a graph showing the results of X-ray diffraction measurement of the mesoporous silica particles obtained in Example 2.

FIG. 5C is a graph showing the results of X-ray diffraction measurement of the mesoporous silica particles obtained in Comparative Example 1.

FIG. 6A is a photograph showing a TEM image of Example 1.

FIG. 6B is a photograph showing a TEM image of Example 1.

FIG. 7A is a photograph showing a TEM image of Example 2.

FIG. 7B is a photograph showing a TEM image of Example 2.

FIG. 8A is a photograph showing a TEM image of Comparative Example 1.

FIG. 8B is a photograph showing a TEM image of Comparative Example 1.

### DESCRIPTION OF EMBODIMENTS

Embodiments of the present invention will be described below.

### [Mesoporous Silica Particles]

Mesoporous silica particles each comprise a core particle comprising mesopores (first mesopores), wherein a periphery of the core particle is covered with silica. Hereinafter, an interior part of a particle, comprising first mesopores is also referred to as a silica core in the present specification. A part formed by silica covering is also referred to as a silica-covered part (or silica shell).

The mesoporous silica particles preferably have a particle diameter of 100 nm or less. They can thus be easily incorporated into a device structure requiring low refractive index (Low-n), low dielectric constant (Low-k) and low thermal conductivity, and the particles can be packed densely inside the device. If the diameter of the mesoporous silica particles is greater than this range, they may not be highly packable. The lower limit of the particle diameter of the mesoporous silica particles is substantially 10 nm. The particle diameter is preferably 20 to 100 nm. Here, the particle diameter of the mesoporous silica particles is a diameter including a silica-covered part, that is, the sum of the particle diameter of a silica core and the thickness of the silica-covered part. The particle diameter of the silica core may be, for example, 20 to 80 nm.

The pore diameter of the first mesopores is preferably 3.0 nm or more, and a plurality of first mesopores are preferably formed with equal spacing in the core particle of each mesoporous particle. Thus, because the first mesopores are equally spaced, strength is not affected when a composition containing the mesoporous particles is molded, as happens when the mesopores are unevenly distributed, so a sufficiently high void ratio can be achieved while maintaining a uniform strength. If the diameter of the first mesopores is less than 3.0 nm, sufficient voids may not be obtained. The diameter of the first mesopores is preferably 10 nm or less. If the diameter of the mesopores is greater than this range, the voids may be too big, making the particles more fragile and reducing the strength of a molded article. Note that equally spaced here does not mean completely equally spaced, and it is sufficient that the pores appear to be at substantially equal distances in TEM observation.

The silica-covered part (silica shell) covering the silica core on the periphery of the core particle may cover the whole silica core or may partially cover the silica core. This can block the first mesopores exposed to the periphery of the silica core or reduce the opening area of the first mesopores.

The thickness of the silica-covered part is preferably 30 nm or less. If the thickness is more than 30 nm, the void volume in the whole particle may be small. When the mesoporous particles are used as a low-refractive index material, the thickness of the silica-covered part is more preferably 10 nm or less because a sufficiently low refractive index can be achieved. The thickness of the silica-covered part is preferably 1 nm or more. If the thickness is less than 1 nm, the amount of coating will be reduced, and the first mesopores may not be sufficiently blocked, or the opening area of the first mesopores may not be reduced.

The silica-covered part preferably comprises second mesopores smaller than the first mesopores. It is possible to increase the void volume of particles while holding the difficulty in the penetration of a resin forming a matrix by comprising second mesopores having a smaller pore diameter than that of the first mesopores.

The pore diameter of the second mesopores is preferably 2 nm or more, and a plurality of second mesopores are preferably formed with equal spacing in the silica-covered part. Thus, because the second mesopores are equally spaced, strength is not affected when a composition containing the mesoporous particles is molded, as happens when the mesopores are unevenly distributed, so a sufficiently high void ratio can be achieved while maintaining a uniform strength. If the diameter of the second mesopores is less than 2 nm, sufficient voids may not be obtained. The diameter of the second mesopores is preferably 90% or less of the diameter of the first mesopores. If the diameter of the second mesopores is larger than this range, the difference between the diameter of the second mesopores and the diameter of the first mesopores may be lost, and the effect of covering may be unlikely to be achieved. Note that equally spaced here does not mean completely equally spaced, and it is sufficient that the pores appear to be at substantially equal distances in TEM observation.

The surfaces of the mesoporous silica particles are preferably provided with organic functional groups. Functions such as dispersibility and reactivity can be enhanced by introducing organic functional groups.

It is desirable that the organic functional groups for modifying the surfaces of the mesoporous silica particles be hydrophobic functional groups. It is thus possible to improve dispersibility in a solvent in the case of a dispersion or improve dispersibility in a resin in the case of a composition. It is thus possible to obtain a molded article in which the particles are uniformly dispersed. Moreover, when molding at high densities, moisture may penetrate the mesopores and other pores during or after molding, degrading product quality. However, hydrophobic functional groups prevent moisture adsorption, resulting in a high-quality molded article.

The hydrophobic functional groups are not particularly limited, but examples include such hydrophobic organic groups as methyl, ethyl, butyl and other alkyl groups and phenyl and other aromatic groups, as well as fluorine substitution products thereof. Preferably, these hydrophobic functional groups are provided in the silica-covered part. It is thus possible to effectively make the particles more hydrophobic and increase dispersibility.

It is also desirable to provide the mesoporous silica particles or the surfaces thereof with reactive functional groups. Reactive functional groups generally mean functional groups that react with the matrix-forming resin. The functional groups on the particles can form chemical bonds by reacting with the resin forming the matrix, thereby improving the strength of the molded article. Preferably, these reactive functional groups are provided in the silica-covered part. It is thus possible to effectively make the particles more reactive and improve the strength of the molded article.

The reactive functional groups are not particularly limited, but are preferably amino, epoxy, vinyl, isocyanate, mercapto, sulfide, ureido, methacryloxy, acryloxy or styryl groups or the like. With these functional groups, it is possible to increase adherence by forming chemical bonds with the resin.

### [Production of Mesoporous Silica Particles]

The method for producing mesoporous silica particles of the present invention is not particularly limited, but the method preferably includes the following steps. The first step is a “surfactant complex silica particle preparation step” of preparing surfactant complex silica particles having mesopores in which surfactant micelles containing a hydrophobic part-containing additive are present as a template. The next step is a “silica covering step” of adding a silica source to the surfactant complex silica particles to thereby cover the surface (periphery) of the silica particles (silica cores) with silica. The final step is a “removal step” of removing the surfactant and the hydrophobic part-containing additive contained in the resulting surfactant complex silica particles.

In the surfactant complex silica particle preparation step, a liquid mixture is first prepared comprising a surfactant, water, an alkali, a hydrophobic part-containing additive and a silica source, the hydrophobic part-containing additive including a hydrophobic part for increasing the volume of micelles to be formed by the surfactant.

Any suitable silica source (silicon compound) capable of forming mesoporous silica particles can be used as the silica source. Examples include silicon alkoxides, and specific examples include tetraalkoxysilanes such as tetramethoxysilane, tetraethoxysilane and tetrapropoxysilane. Of these, it is particularly desirable to use tetraethoxysilane (Si(OC₂H₅)₄) because it allows good mesoporous silica particles to be prepared with ease.

The silica source preferably contains an alkoxysilane having an organic functional group. Using the alkoxysilane, it is possible to form a silica framework out of alkoxysilyl groups while disposing organic functional groups on the surfaces of the particles. Since these organic functional groups will react with a resin to form chemical bonds when the particles are complexed with the resin, it is also possible to easily produce mesoporous silica particles that enhance the strength of a molded article. It is further possible to give suitable properties to the mesoporous silica particles by chemically modifying the organic functional group with other organic molecules or the like.

The alkoxysilane having an organic functional group is not particularly limited as long as it can yield a surfactant complex silica particle when used as a component of the silica source. Examples include alkoxysilanes comprising alkyl, aryl, amino, epoxy, vinyl, mercapto, sulfide, ureido, methacryloxy, acryloxy and styryl groups as organic groups. Of these, an amino group is preferred, and a silane coupling agent such as aminopropyltriethoxysilane can be used by preference. Surface modification via an amino group can be accomplished, for example, by a reaction with a modifying agent having an isocyanate group, an epoxy group, a vinyl group, a carboxyl group, a Si—H group or the like.

A cationic surfactant, an anionic surfactant, a non-ionic surfactant or a triblock copolymer can be used as the surfactant, but it is desirable to use a cationic surfactant. The cationic surfactant is not particularly limited, but octadecyl trimethyl ammonium bromide, hexadecyl trimethyl ammonium bromide, tetradecyl trimethyl ammonium bromide, dodecyl trimethyl ammonium bromide, decyl trimethyl ammonium bromide, octyl trimethyl ammonium bromide, hexyl trimethyl ammonium bromide and other quaternary ammonium salt-type cationic surfactants are especially desirable because they allow easy preparation of good mesoporous silica particles.

The mixing ratio of the silica source to the surfactant is not particularly limited, but a weight ratio of 1:10 to 10:1 is preferred. If the amount of the surfactant is outside this range relative to the silica source, the structure of the product may be less regular, and it may be difficult to obtain mesoporous silica particles with a regular arrangement of mesopores. It is possible to easily obtain mesoporous silica particles with a regular arrangement of mesopores particularly when the ratio is in the range of 100:75 to 100:100.

The hydrophobic part-containing additive is an additive having a hydrophobic part that has the effect of increasing the volume of micelles to be formed by the surfactant as described above. By including a hydrophobic part-containing additive, it is possible to obtain mesoporous silica particles with large first mesopores because this additive increases the volume of the micelles when it is incorporated into the hydrophobic part of the surfactant micelles in the course of the alkoxysilane hydrolysis reaction. The hydrophobic part-containing additive is not particularly limited, but examples in which the entire molecule is hydrophobic include alkylbenzenes, long-chain alkanes, benzene, naphthalene, anthracene and cyclohexane, while examples in which part of the molecule is hydrophobic include block copolymers. Methylbenzene, ethylbenzene, isopropylbenzene and other alkylbenzenes are particularly desirable because they are easily incorporated into the micelles and more likely to enlarge the first mesopores.

Note that the technique of adding a hydrophobic additive to enlarge mesopores when preparing a mesoporous material is disclosed in the prior documents, J. Am. Chem. Soc. 1992, 114, 10834-10843 and Chem. Mater. 2008, 20, 4777-4782. However, in the production method of the present invention, mesoporous silica particles with a higher void ratio have been obtained by enlarging the mesopores while maintaining particles with good dispersibility suited to a precision device by using methods such as those described above.

The molar ratio of the amount of the hydrophobic part-containing additive to the amount of the surfactant in the liquid mixture is preferably three times or more. It is thus possible to obtain mesopores of sufficient size, and to easily prepare particles with a higher void ratio. If the amount of the hydrophobic part-containing additive relative to the amount of the surfactant is less than three times, the mesopores may not be sufficiently large. Even if the hydrophobic part-containing additive is contained in an excessive amount, the excessive hydrophobic part-containing additive will not be incorporated into the micelles and is unlikely to have much effect on the particle reaction. Therefore, although the upper limit of the amount of the hydrophobic part-containing additive is not particularly limited, it is preferably 100 times or less the amount of the surfactant from the standpoint of the efficiency of the hydrolysis reaction. More preferably, it is three times or more and 50 times or less.

The liquid mixture preferably contains an alcohol. By including an alcohol in the liquid mixture, it is possible to control the size and shape of the polymer when polymerizing the silica source, producing particles that are nearly spherical and uniform in size. The size and shape of the particles are likely to be irregular when an alkoxysilane having an organic functional group is used as the silica source in particular. However, by including an alcohol in this case, it is possible to prevent deviations in shape and the like caused by the organic functional group, and to standardize the size and shape of the particles.

The prior document, Microporous and Mesoporous Materials 2006, 93, 190-198 discloses that mesoporous silica particles with different shapes can be prepared using various alcohols. However, in the method of this document, the mesopores are insufficiently large, and particles with a high void ratio cannot be formed. In the present invention, by contrast, although particle growth is inhibited when an alcohol is added to a mixture such as that described above, it is still possible to obtain core particles with large first mesopores.

The alcohol is not particularly limited, but a polyvalent alcohol having two or more hydroxyl groups is desirable for obtaining good control of particle growth. A suitable polyvalent alcohol can be used, but for example, ethylene glycol, glycerin, 1,3-butylene glycol, propylene glycol, polyethylene glycol or the like is preferably used. The amount of the alcohol mixed is not particularly limited, but is preferably about 1,000 to 10,000 mass %, more preferably about 2,200 to 6,700 mass %, of the silica source.

Next, in the surfactant complex silica particle preparation step, the liquid mixture is mixed and stirred to prepare surfactant complex silica particles. The mixing and stirring causes a hydrolysis reaction of the silica source by means of the alkali, polymerizing the silica source. In preparing the above liquid mixture, the liquid mixture may also be prepared by adding the silica source to a liquid mixture comprising a surfactant, water, an alkali and a hydrophobic part-containing additive.

An inorganic or organic alkali suitable for synthesizing surfactant complex silica particles can be used as the alkali in the reaction. Of these, an ammonium or amine alkali (nitrogenous alkali) is preferred, and it is especially desirable to use highly reactive ammonia. When using ammonia, ammonia water is preferred from a safety standpoint.

The mixing ratio of the silica source to the dispersion solvent (including water and in some cases alcohol) in the liquid mixture is preferably 5 to 1,000 parts by mass of dispersion solvent per 1 part by mass of the condensed compound obtained by hydrolysis of the silica source. If the amount of dispersion solvent is less than this range, the silica source may be too concentrated, increasing the reaction rate and making it difficult to stably form regular meso-structures. On the other hand, if the amount of the dispersion solvent is above this range, the yield of mesoporous silica particles may be very low, which is impractical from a manufacturing standpoint.

The surfactant complex silica particles prepared in the surfactant complex silica particle preparation step constitute the silica cores of the mesoporous silica particles.

In the silica covering step, a silica source is further added to the surfactant complex silica particles (silica cores) to thereby cover the periphery of the silica core particles, that is, the surface of the silica cores, with silica. The covering of the surface may be performed by the same material and under the same conditions as in the surfactant complex silica particle preparation step. If the surfactant is used and the hydrophobic part-containing additive is not used in the silica covering step, second mesopores smaller than the first mesopores can be easily formed in the silica-covered part.

For example, a liquid mixture comprising surfactant complex silica particles, water, an alkali and a silica source is first prepared. The surfactant complex silica particles obtained in the step as described above may be used without purification. If a surfactant is used, the second mesopores can be easily formed because micelles are formed in the reaction solution.

As a silica source, the same one as is used in the surfactant complex silica particle preparation step may be used, or a different one may be used. Production will be simple if the same one is used. If an alkoxysilane having an organic functional group is used as a silica source, the surface of the silica-covered part can be modified.

As a surfactant, the same one as is used in the surfactant complex silica particle preparation step may be used, or a different one may be used. Production will be simple if the same one is used.

The mixing ratio of the silica source to the surfactant is not particularly limited, but a weight ratio of 1:10 to 10:1 is preferred. If the amount of the surfactant is outside this range relative to the silica source, the structure of the product may be less regular, and it may be difficult to obtain mesoporous silica particles with a regular arrangement of mesopores. It is possible to easily obtain mesoporous silica particles with a regular arrangement of mesopores particularly when the ratio is in the range of 100:75 to 100:100.

The liquid mixture preferably contains an alcohol. By including an alcohol in the liquid mixture, it is possible to control the size and shape of the polymer when polymerizing the silica source, producing particles that are nearly spherical and uniform in size. The size and shape of the particles are likely to be irregular when an alkoxysilane having an organic functional group is used as the silica source in particular. However, by including an alcohol in this case, it is possible to prevent deviations in shape and the like caused by the organic functional group, and to standardize the size and shape of the particles.

The alcohol is not particularly limited, but a polyvalent alcohol having two or more hydroxyl groups is desirable for obtaining good control of particle growth. A suitable polyvalent alcohol can be used, but for example, ethylene glycol, glycerin, 1,3-butylene glycol, propylene glycol, polyethylene glycol or the like is preferably used. The amount of the alcohol mixed is not particularly limited, but is preferably about 1,000 to 10,000 mass %, more preferably about 2,200 to 6,700 mass %, of the silica source.

Next, in the silica covering step, the liquid mixture is mixed and stirred to prepare a silica-covered part on a periphery of the surfactant complex silica particles. The mixing and stirring causes a hydrolysis reaction of the silica source by means of the alkali, polymerizing the silica source to form a silica-covered part on a periphery of the core particles. Note that, in preparing the above liquid mixture, the liquid mixture may also be prepared by adding the surfactant complex silica particles to a liquid mixture comprising a surfactant, water, an alkali and a silica source.

As the alkali used in the reaction, the same one as is used in the surfactant complex silica particle preparation step may be used, or a different one may be used. Production will be simple if the same one is used.

Note that the mixing ratio of the surfactant complex silica particles to the silica source to be added in the liquid mixture is preferably 0.1 to 10 parts by mass of the silica source per 1 part by mass of the silica source forming the surfactant complex silica particles. If the amount of the silica source is less than this range, a sufficient covering may not be obtained. On the other hand, if the amount of the silica source is greater than this range, the silica-covered part may be too thick to obtain a sufficient effect by voids.

In the silica covering step, it is particularly preferred to use tetraethoxysilane (TEOS) as a silica source. It is further preferred to use a mixture of TEOS with γ-aminopropyltriethoxysilane (APTES) and hexadecyltrimethylammonium bromide (CTAB). The amount of TEOS blended may be 0.1 to 10 parts by mass per 1 part by mass of the silica source forming the surfactant complex silica particles. The amount of APTES blended may be 0.02 to 2 parts by mass per 1 part by mass of the silica source forming the surfactant complex silica particles. The amount of CTAB blended may be 0.1 to 10 parts by mass per 1 part by mass of the silica source forming the surfactant complex silica particles.

It is also preferred to perform the silica covering step in a plurality of times, for example, two times or more or three times or more. This allows a multiple-layer silica-covered part to be obtained, allowing the opening of the first mesopores to be further blocked.

The stirring temperature in the silica covering step is preferably room temperature (for example, 25° C.) to 100° C. The stirring time in the silica covering step is preferably 30 minutes to 24 hours. When the stirring temperature and the stirring time are set in these ranges, it is possible to form a sufficient silica-covered part on a periphery of the core particle while increasing the production efficiency.

After covering each surfactant complex silica particle (silica core) with a silica-covered part (silica shell) in the silica covering step, the surfactant and the hydrophobic part-containing additive contained in the resulting surfactant complex silica particle are removed in a removal step. Mesoporous silica particles in which the first mesopores and the second mesopores are formed as voids can be obtained by removing the surfactant and the hydrophobic part-containing additive.

One way to remove the surfactant and the hydrophobic part-containing additive constituting the template of the silica particles complexed with the surfactant is by baking the surfactant complex silica particles at a temperature that decomposes the template. However, in the removal step, it is desirable to remove the template by extraction in order to prevent aggregation and improve the dispersibility of the particles in a medium. For example, the template can be removed by acid extraction.

It is further preferred to include the step of mixing an alkyldisiloxane with the acid to thereby remove the surfactant from the first mesopores and the second mesopores of the surfactant complex silica particles and silylate the surface of the surfactant complex silica particles. In this case, the acid extracts the surfactant in the mesopores and at the same time can activate the siloxane bond of the organosilicon compound by a cleavage reaction to alkylsilylate the silanol group on the surface of the silica particles. This silylation can protect the surface of the particles with a hydrophobic group to prevent the first mesopores and the second mesopores from being destroyed by the hydrolysis of the siloxane bond. It is also possible to inhibit particle aggregation, which may occur due to the condensation of silanol groups between particles.

As the alkyldisiloxane, it is preferred to use hexamethyldisiloxane. When hexamethyldisiloxane is used, a trimethylsilyl group can be introduced, allowing protection with a small functional group.

The acid that is mixed with the alkyldisiloxane can be any that has the effect of cleaving the siloxane bond, and for example, hydrochloric acid, nitric acid, sulfuric acid, hydrogen bromide or the like can be used. The acid is preferably compounded in such a way that the pH of the reaction liquid is less than 2 in order to expedite surfactant extraction and cleavage of the siloxane bond.

A suitable solvent is preferably used when mixing the acid and the organosilicon compound having a siloxane bond in the molecule. Using a solvent facilitates mixing. An alcohol with amphiphilic properties is preferably used as the solvent in order to allow the hydrophilic silica nanoparticles to be compatible with the hydrophobic alkyldisiloxane. For example, isopropanol may be used.

The reaction by using the acid and the alkyldisiloxane can be performed in a reaction liquid in which the surfactant complex silica particles are synthesized and then a reaction of forming the silica-covered part was performed, using the reaction liquid on an “as is” basis. This means that there is no need to separate and recover the particles from the liquid after the synthesis of the surfactant complex silica particles or the formation of the silica-covered part. The production process can be simplified because the separation and recovery step can be omitted. Moreover, since there is no separation and recovery step, the surfactant complex silica particles can be allowed to uniformly react without causing aggregation, and it is possible to obtain mesoporous silica particles in a particle state.

In the removal step, for example, an acid and an alkyldisiloxane can be mixed into the reaction liquid after the formation of the silica-covered part, and stirred for about 1 minute to 50 hours, preferably for about 1 minute to 8 hours, with heating at about 40 to 150° C., preferably about 40 to 100° C., to thereby extract the surfactant from the mesopores by the acid while at the same time causing a cleavage reaction of the alkyldisiloxane by the acid, activating the alkyldisiloxane to alkylsilylate the first mesopores, the second mesopores and the particle surfaces.

The surfactant complex silica particles preferably have on the surface thereof functional groups that are not silylated when mixed with an acid and an alkyldisiloxane. Since functional groups that are not silylated remain on the surfaces of the mesoporous silica particles, the surfaces of the mesoporous silica particles can be easily treated with or can form chemical bonds with a substance that reacts with these functional groups. It is thus easy to accomplish a surface treatment reaction in which chemical bonds are formed by a reaction between the mesoporous silica particles and functional groups in the resin forming the matrix. Such functional groups can be obtained by incorporating them into the silica source in the steps as described above.

The functional groups that are not silylated when mixed with an acid and an organosilicon compound having a siloxane bond in the molecule are not particularly limited, but are preferably amino, epoxy, vinyl, mercapto, sulfide, ureido, methacryloxy, acryloxy or styryl groups or the like.

The mesoporous particles prepared in the removal step can be recovered by centrifugation, filtration or the like and then dispersed in a medium, or subjected to media exchange by dialysis or the like to be used in a dispersion, composition or molded article.

According to the method for producing mesoporous silica particles as described above, it is possible to form mesoporous silica particles in the form of particulates with increased voids by forming first mesopores with a surfactant and increasing the diameter of micelles by the incorporation of a hydrophobic part-containing additive into the micelles formed by the surfactant when advancing the hydrolysis reaction of alkoxysilane under an alkali condition. Thus, it is possible to obtain mesoporous silica particles which can inhibit the penetration of a matrix-forming material into mesopores by the covering with silica.

### [Molded Article]

A mesoporous silica particle-containing composition can be obtained by incorporating the mesoporous silica particles as described above into a matrix-forming material. A molded article having the functions of low refractive index (Low-n), low dielectric constant (Low-k) and low thermal conductivity can be easily produced with this mesoporous silica particle-containing composition. It is possible to produce a uniform molded article because the mesoporous silica particles are uniformly dispersed in the matrix-forming material in the composition.

The matrix-forming material is not particularly limited as long as it does not impair the dispersibility of the mesoporous silica particles. Examples thereof include polyester resins, acrylic resins, urethane resins, vinyl chloride resins, epoxy resins, melamine resins, fluororesin, silicone resins, butyral resins, phenol resins, vinyl acetate resins and fluorene resins. These may also be ultraviolet curable resins, thermosetting resins, electron beam curable resins, emulsion resins, water-soluble resins, hydrophilic resins, mixtures thereof, co-polymers or modified forms of these resins, or alkoxysilanes or other hydrolysable organosilicon compounds or the like. Additives may also be added to the composition as necessary. Examples of additives include light-emitting materials, conductive materials, color-forming materials, fluorescent materials, viscosity-adjusting materials, resin curing agents and resin curing accelerators.

A mesoporous silica particle-containing molded article can be obtained by molding using the mesoporous silica particle-containing composition as described above. It is thus possible to obtain a molded article having the functions of low refractive index (Low-n), low dielectric constant (Low-k) and low thermal conductivity. Moreover, since the mesoporous silica particles have good dispersibility, these particles are uniformly arranged in the matrix in the molded article, resulting in a molded article with little variation in performance. Moreover, since the mesoporous silica particles are covered with silica, it is possible to obtain a molded article in which the penetration of the matrix-forming material into the mesopores of the mesoporous silica particles is inhibited.

The method of preparing the molded article containing mesoporous silica particles is not particularly limited as long as it is capable of forming a composition containing mesoporous silica particles into an arbitrary shape, and examples include printing, coating, extrusion, vacuum molding, injection molding, laminate molding, transfer molding and foam molding.

In coating on the surface of a substrate, the method of the coating is not particularly limited, but various ordinary coating methods can be selected such as brush coating, spray coating, dipping (dip coating), roll coating, flow coating, curtain coating, knife coating, spin coating, table coating, sheet coating, leaf coating, die coating, bar coating, doctor blade coating and the like. A method such as cutting or etching can be used to process a solid body into a desired shape.

In a molded article, the mesoporous silica particles are preferably chemically bonded to form a complex with the matrix-forming material. This allows the mesoporous silica particles to adhere more strongly to the resin. Note that the complex-formation means a state of forming a complex by chemical bonds.

The structure of the chemical bonds is not particularly limited as long as the functional groups serve to chemically bond the mesoporous silica particles and matrix-forming material on the surfaces of both, but if one side has amino groups, the other preferably has isocyanate, epoxy, vinyl, carbonyl or Si—H groups or the like, and in this case chemical bonds can be easily formed by a chemical reaction.

The molded article is preferably provided with one or two or more of the functions of high transparency, low dielectric constant, low refractive index and low thermal conductivity. A high-quality device can be manufactured if the molded article provides any of the functions of high transparency, low dielectric constant, low refractive index and low thermal conductivity. A multifunctional molded article can be obtained if two or more of these functions are provided, making it possible to manufacture a device that requires multifunctionality. That is, a molded article containing mesoporous silica particles has the performances of excellent uniformity, high transparency, low refractive index (Low-n), low dielectric constant (Low-k) and low thermal conductivity.

Specific examples of the molded article using the properties of the low refractive index (Low-n) include an organic electroluminescent element and an antireflective film.

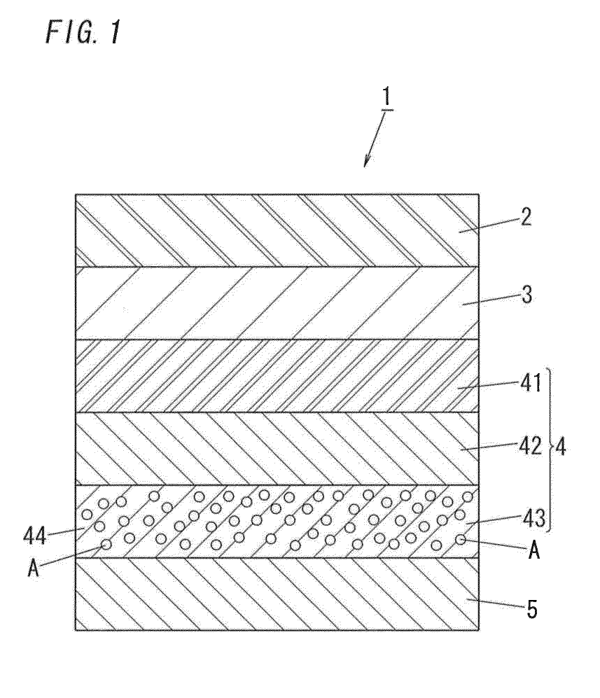

FIG. 1 shows an example in the form of organic electroluminescent elements (hereinafter, organic EL elements).

An organic EL element 1 shown in FIG. 1 is configured by laminating a first electrode 3, an organic layer 4 and a second electrode 5 on a surface of a substrate 2 in this order from the first electrode 3 side. The substrate 2 is in contact with the outside (for example, atmospheric air) at the surface opposite to the first electrode 3. The first electrode 3 has optical transparency and functions as an anode of the organic EL element 1. The organic layer 4 is configured by laminating a hole injection layer 41, a hole transport layer 42 and a light-emitting layer 43 in this order from the first electrode 3 side. The light-emitting layer 43 comprises a light-emitting material 44 in which mesoporous silica particles A are dispersed. The second electrode 5 has light-reflecting properties and functions as a cathode of the organic EL element 1. Note that a hole blocking layer, an electron transport layer and an electron injection layer may be further laminated between the light-emitting layer 43 and the second electrode 5 (not shown). In the organic EL element 1 configured in this way, when a voltage is applied between the first electrode 3 and the second electrode 5, the first electrode 3 injects holes into the light-emitting layer 43, and the second electrode 5 injects electrons into the light-emitting layer 43. Excitons are generated when these holes and electrons are recombined with each other in the light-emitting layer 43, and light is emitted when the excitons return to their ground state. The light emitted in the light-emitting layer 43 is transmitted through the first electrode 3 and the substrate 2 and is extracted outside.

Since the light-emitting layer 43 contains the mesoporous silica particles A as described above, it can have a low refractive index to increase luminescence and also can be a light-emitting layer 43 with high strength. Note that the light-emitting layer 43 may have a multilayer structure. For example, it is possible to prepare a multilayer structure by forming the outer layer (or a first layer) of the light-emitting layer 43 with a light-emitting material which does not contain the mesoporous silica particles A, and forming the inner layer (or a second layer) of the light-emitting layer 43 with a light-emitting material containing the mesoporous silica particles A. In this case, a larger amount of the light-emitting material can contact with another layer in the contact surface therewith, leading to higher emission intensity.

### EXAMPLES

Hereinafter, the present invention will be specifically described with reference to Examples.

### Production of Mesoporous Silica Particles

### Example 1

### Synthesis of Surfactant Complex Silica Particles

In a separable flask equipped with a condenser tube, a stirrer and a thermometer, 120 g of H₂O, 6.4 g of a 25% aqueous NH₃ solution, 20 g of ethylene glycol, 1.20 g of hexadecyltrimethylammonium bromide (CTAB), 1.54 g of 1,3,5-trimethylbenzene (TMB) (TMB/CTAB molar ratio=4), 1.29 g of tetraethoxysilane (TEOS) and 0.23 g of γ-aminopropyltriethoxysilane (APTES) were mixed and stirred at 60° C. for 4 hours to prepare surfactant complex silica particles.

### Formation of Silica-Covered Part:

To the reaction solution of the surfactant complex silica particles, were added 1.29 g of TEOS and 0.23 g of APTES and stirred for 2 hours.

### Extraction of Template and Preparation of Isopropanol Dispersion:

To a mixture of 30 g of isopropanol, 60 g of 5N-HCl and 26 g of hexamethyldisiloxane which were mixed and stirred at 72° C., was added the synthesis reaction solution prepared above that contained the surfactant complex silica particles, followed by stirring and reflux for 30 minutes. With these operations, the surfactant and the hydrophobic part-containing additive were extracted from the surfactant complex silica particles, yielding a dispersion of mesoporous silica particles.

The dispersion of mesoporous silica particles was centrifuged at 12,280 G for 20 minutes, followed by removing the liquid. Ethanol was added to the precipitated solid phase, and the particles were shaken in ethanol with a shaker to wash the mesoporous silica particles. The resulting mixture was centrifuged at 12,280 G for 20 minutes, followed by removing the liquid to obtain mesoporous silica particles.

To 0.2 g of the mesoporous silica particles prepared, was added 3.8 g of isopropanol to re-disperse the particles with a shaker to obtain mesoporous silica particles dispersed in isopropanol.

### Example 2

Surfactant complex silica particles were synthesized in the same manner as in Example 1. To the reaction solution of the surfactant complex silica particles, was added 8.4 g of CTAB and stirred at 60° C. for 10 minutes, and then thereto were added 1.29 g of TEOS and 0.23 g of APTES and stirred for 2 hours to form the silica-covered part. The template was extracted and the isopropanol dispersion was prepared under the same conditions as in Example 1.

### Comparative Example 1

Mesoporous silica particles were obtained by synthesizing surfactant complex silica particles and extracting the template followed by washing the particles under the same conditions as in Example 1 except that the silica-covered part was not formed. These mesoporous silica particles were dispersed in isopropanol.

### [Structural Comparison of Mesoporous Silica Particles]

The mesoporous silica particles of Examples 1 and 2 and Comparative Example 1 were heat treated for 2 hours at 150° C. to obtain dry powders, which were then subjected to nitrogen adsorption measurement and X-ray diffraction measurement.

### (Nitrogen Adsorption Measurement)

The adsorption isotherm was measured with an Autosorb-3 (manufactured by Quantachrome Instruments). The pore diameter distribution was obtained by the BJH analysis method.

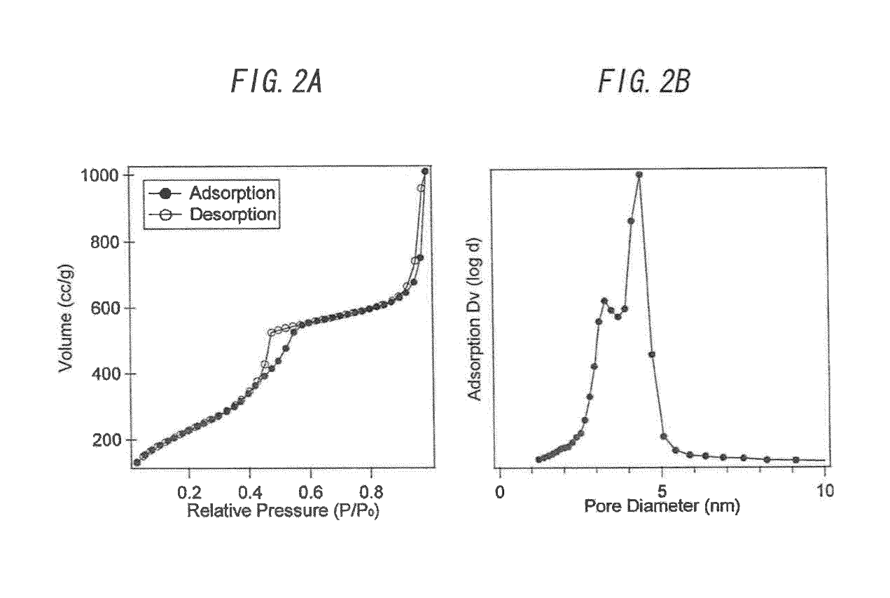

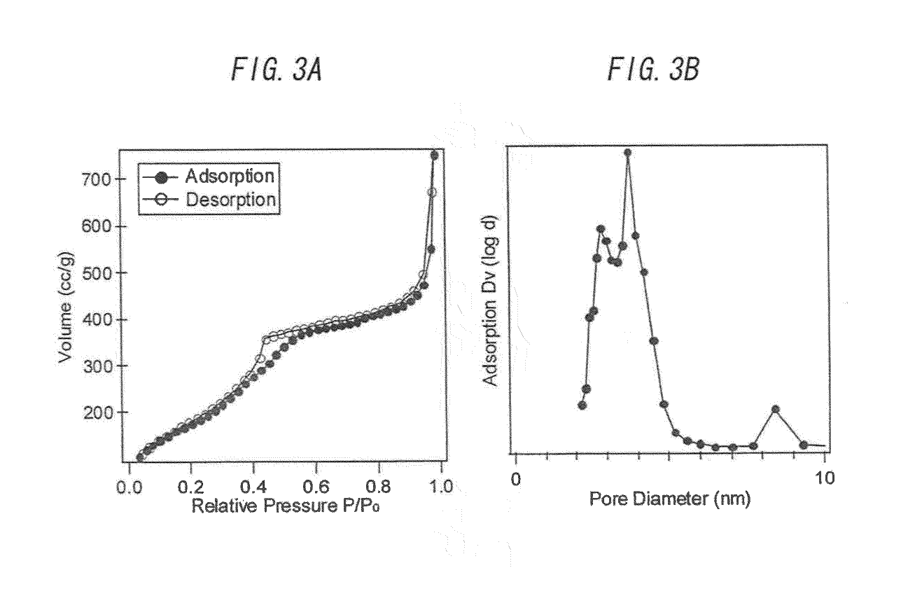

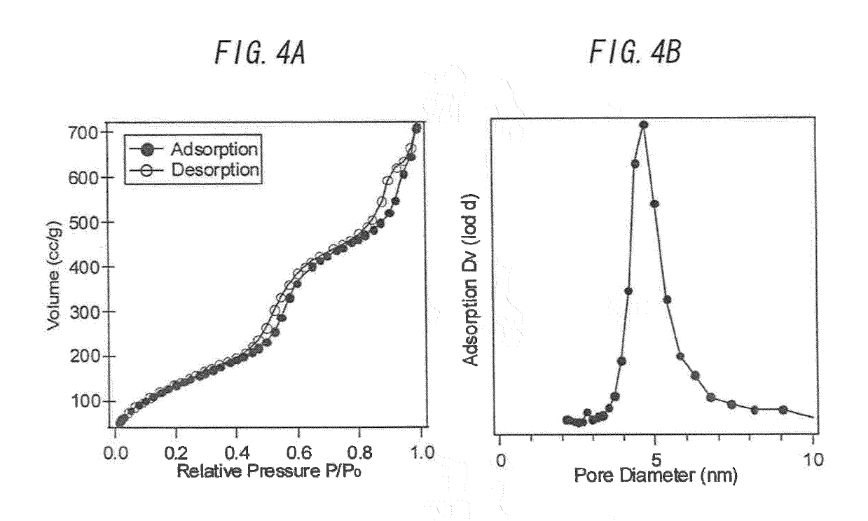

With respect to the adsorption isotherm, the results of Example 1 are shown in FIG. 2A; the results of Example 2 are shown in FIG. 3A; and the results of Comparative Example 1 are shown in FIG. 4A. With respect to the pore diameter distribution, the results of Example 1 are shown in FIG. 2B; the results of Example 2 are shown in FIG. 3B; and the results of Comparative Example 1 are shown in FIG. 4B. The BET specific surface area, pore volume and pore diameter are shown in Table 1.

The BET specific surface area and pore volume of the particles of Examples 1 and 2 are equivalent to those of the particles of Comparative Example 1, showing that high void ratio is held. It was found that two types of mesopores having different pore diameters were present in the particles of Example 1, that is, the first mesopores having a pore diameter of 4.4 nm and the second mesopores having a pore diameter of 3.3 nm. It was found that two types of mesopores having different pore diameters were also present in the particles of Example 2, that is, the first mesopores having a pore diameter of 3.7 nm and the second mesopores having a pore diameter of 2.8 nm. These results have revealed that the second mesopores smaller than the first mesopores are formed in the particles of Examples 1 and 2. On the other hand, it was verified that only the first mesopores having a pore diameter of 4.7 nm were formed in the particles of Comparative Example 1.

TABLE 1

| | BET specific | | BJH pore |
|---|---|---|---|
| | surface area | Pore volume | diameter |
| | [m² g⁻¹] | [cm³ g⁻¹] | [nm] |
| Example 1 | 878 | 1.6 | 3.3, 4.4 |
| Example 2 | 670 | 1.2 | 2.8, 3.7 |
| Comparative | 550 | 1.1 | 4.7 |
| Example 1 | | | |

### (X-Ray Diffraction Measurement)

X-ray diffraction measurement was performed on the mesoporous silica particles of Examples and Comparative Example, using an AXS M03X-HF (manufactured by Bruker Corporation).

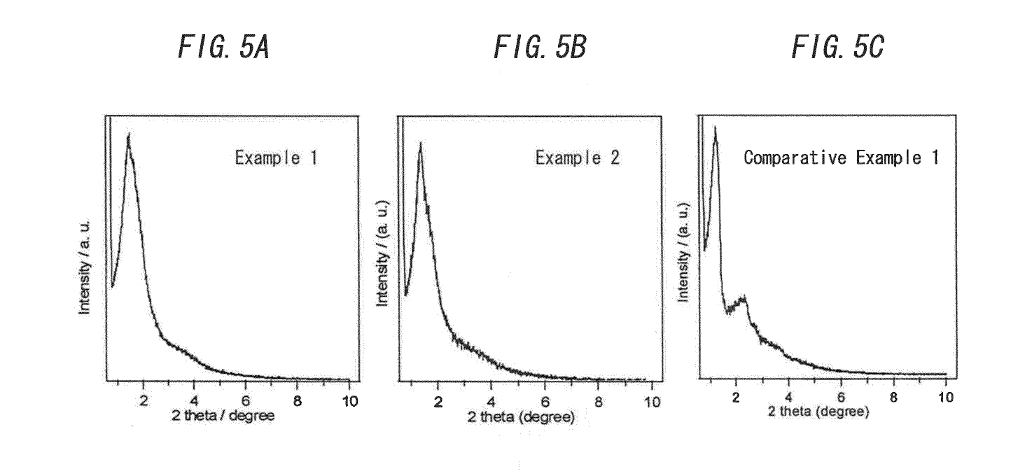

FIG. 5 shows the results of the measurement of the mesoporous silica particles of Examples 1 and 2 and Comparative Example 1. FIG. 5A shows the results of Example 1; FIG. 5B shows the results of Example 2; and FIG. 5C shows the results of Comparative Example 1. Peaks attributable to regular structures of mesopores were confirmed in all of the mesoporous silica particles of Examples 1 and 2 and Comparative Example 1.

### (TEM Observation)

The fine structures of the mesoporous silica particles of Examples 1 and 2 and Comparative Example 1 were observed by TEM using a JEM 2000EXII (manufactured by JEOL Ltd.).

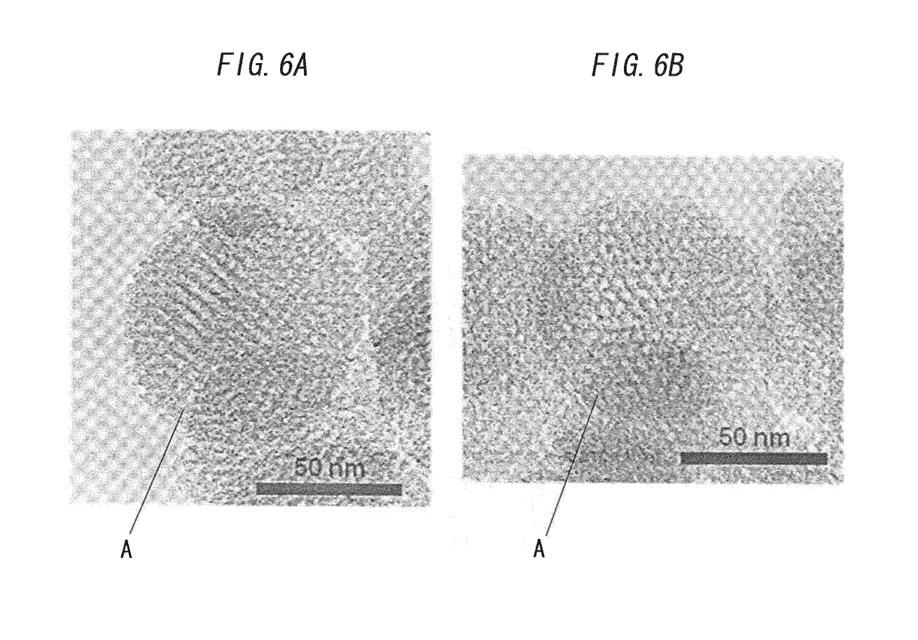

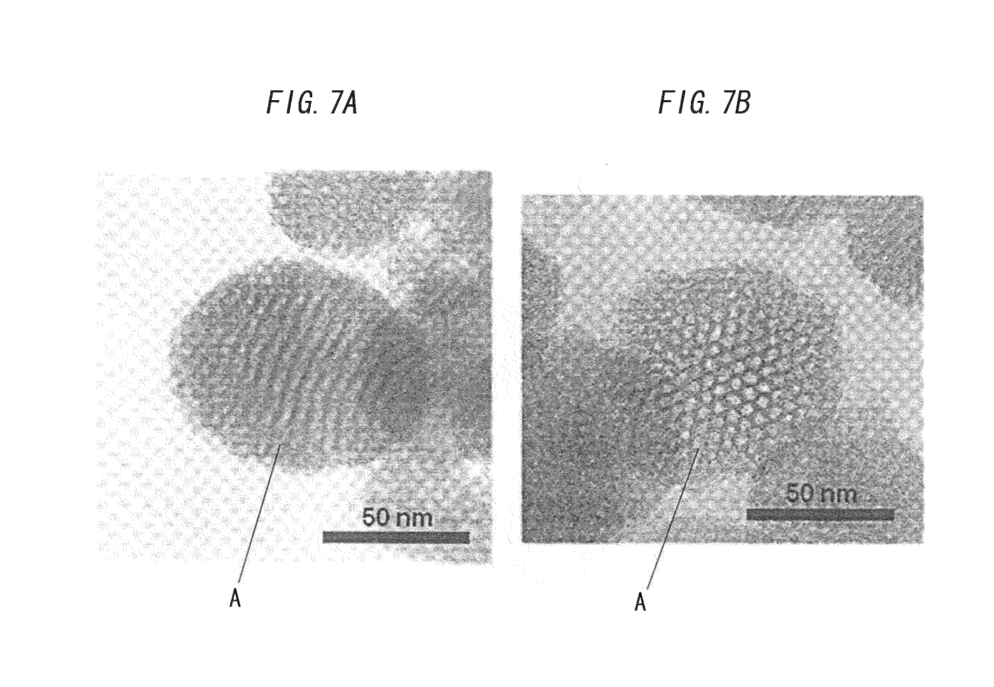

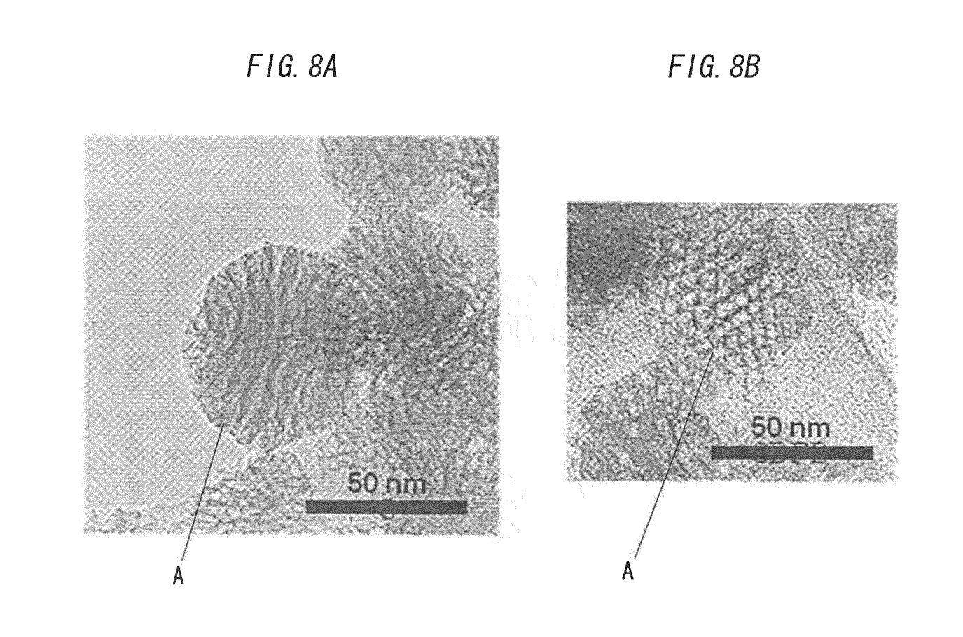

With respect to the mesoporous silica particles A, a TEM image of Example 1 is shown in FIG. 6A and FIG. 6B; a TEM image of Example 2 is shown in FIG. 7A and FIG. 7B; and a TEM image of Comparative Example 1 is shown in FIG. 8A and FIG. 8B.

The particle diameter was about 70 nm in Examples 1 and 2 while it was about 50 nm in Comparative Example 1. Thus, it was verified that a silica-covered part having a thickness of about 10 nm was formed by regrowth, increasing the particle diameter. The regular arrangement of mesopores each having a pore diameter exceeding 4 nm was verified in the interior of the particles in Example 1; and the regular arrangement of mesopores each having a pore diameter of about 4 nm was verified in the interior of the particles in Example 2. These are thought to be the first mesopores verified by the nitrogen adsorption measurement. Therefore, it is thought that the second mesopores having pore diameters of 3.3 nm in Example 1 and 2.8 nm in Example 2, respectively, which were verified by the nitrogen adsorption measurement, are formed in the silica-covered part. On the other hand, the regular arrangement of mesopores having a pore diameter exceeding 4 nm was verified on the whole particles in Comparative Example 1.

### Organic EL Element

### Example A1

An organic EL element having a layered structure as shown in FIG. 1 was prepared.

A non-alkali glass plate having a thickness of 0.7 mm (No. 1737, manufactured by Corning Incorporated) was used as the substrate 2. The surface of the substrate 2 was sputtered using an ITO target (manufactured by TOSOH Corporation) to form an ITO layer having a thickness of 150 nm. The resulting glass substrate with an ITO layer was annealed at 200° C. for 1 hour in an Ar atmosphere to form the first electrode 3 as an optically transparent anode having a sheet resistance of 18Ω/□. When a refractive index at a wavelength of 550 nm was measured by a FilmTek manufactured by Scientific Computing International, it was found to be 2.1.

Next, polyethylenedioxythiophene/polystyrene sulfonate (PEDOT-PSS) (“Baytron P AI4083” manufactured by H.C. Starck-V TECH Ltd., PEDOT:PSS=1:6) was applied to the surface of the first electrode 3 by a spin coater so as to have a film thickness of 30 nm and then baked at 150° C. for 10 minutes to form the hole injection layer 41. The refractive index of the hole injection layer 41 at a wavelength of 550 nm was 1.55 when measured in the same manner as for the first electrode 3.

Next, a solution of TFB (poly[(9,9-dioctylfluorenyl-2,7-diyl)-co-(4,4′-(N-(4-sec-butylphenyl))diphenylamine)]) (“Hole Transport Polymer ADS259BE” manufactured by American Dye Source, Inc.) in THF solvent was applied to the surface of the hole injection layer 41 by a spin coater so as to have a film thickness of 12 nm to prepare a TFB coating film. The coating film was baked at 200° C. for 10 minutes to form the hole transport layer 42. The refractive index of the hole transport layer 42 at a wavelength of 550 nm was 1.64.

Next, a solution of a red polymer (“Light Emitting Polymer ADS111RE” manufactured by American Dye Source, Inc.) in THF solvent was applied to the surface of the hole transport layer 42 by a spin coater so as to have a film thickness of 20 nm and then baked at 100° C. for 10 minutes to form a red polymer layer to serve as the outer layer of the light-emitting layer 43.

A dispersion of the mesoporous silica particles prepared in Example 1 in 1-butanol was applied to the surface of the red polymer layer, and thereto was further applied the red polymer ADS111RE by a spin coater so as to have a thickness of the layers formed by the application of the mesoporous silica particles and the application of the red polymer of 100 nm in total. Then, these layers were baked at 100° C. for 10 minutes to obtain the light-emitting layer 43. The total thickness of the light-emitting layer 43 was 120 nm. The refractive index of the light-emitting layer 43 at a wavelength of 550 nm was 1.53.

Finally, Ba of 5 nm thick and aluminum of 80 nm thick were deposited on the surface of the light-emitting layer 43 by a vacuum deposition method to prepare the second electrode 5.

Thus, the organic EL element 1 of Example A1 was obtained.

### Comparative Example A1

The organic EL element of Comparative Example A1 was obtained in the same manner as in Example A1 except that the mesoporous silica particles of Comparative Example 1 which were not subjected to the surface-covering treatment with silica were used as the particles to be mixed into the light-emitting layer 43. In this case, the refractive index of the light-emitting layer 43 at a wavelength of 550 nm was 1.55.

### Comparative Example A2

The organic EL element was obtained in the same manner as in Example A1 except that the mesoporous silica particles were not mixed into the light-emitting layer. In this case, the refractive index of the light-emitting layer 43 at a wavelength of 550 nm was 1.67.

### (Evaluation Test)

The evaluation test was performed on the organic EL elements 1 of Example A1 and Comparative Examples A1 and A2 prepared as described above. In the present evaluation test, an electrical current having a current density of 10 mA/cm² was applied between the electrodes 3 and 5 (refer to FIG. 1), and the light emitted to the atmosphere was measured using an integrating sphere. A hemispherical lens made of glass was disposed on the emitting surface of the organic EL element 1 through a matching oil having the same refractive index as the glass, and the light reaching the substrate 2 from the light-emitting layer 43 was measured in the same manner as described above. Then, the external quantum efficiency of the light emitted to the atmosphere and the external quantum efficiency of the light reaching the substrate were calculated based on the results of the measurement. The external quantum efficiency of the light emitted to the atmosphere is calculated from the electrical current supplied to the organic EL element 1 and the amount of the light emitted to the atmosphere, and the external quantum efficiency of the light reaching the substrate is calculated from the electrical current supplied to the organic EL element 1 and the amount of the light reaching the substrate.

The results of the evaluation test are shown in Table B below. The respective external quantum efficiencies of the light emitted to the atmosphere and the light reaching the substrate of the organic EL elements 1 were calculated on the basis of the Comparative Example 2.

The results are shown in Table 2.

TABLE 2

| | |
|---|---|
| Refractive | External quantum |
| index of | efficiency ratio |

| | light- | | Light |
|---|---|---|---|
| | emitting | Light emitted | reaching |
| | layer | to atmosphere | substrate |
| Example A1 | 1.53 | 1.12 | 1.38 |
| Comparative | 1.55 | 1.07 | 1.23 |
| Example A1 | | | |
| Comparative | 1.67 | 1.01 | 1.00 |
| Example A2 | | | |

As shown in Table 2, the organic EL elements 1 of Example A1 and Comparative Example A1 using the mesoporous silica particles had higher external quantum efficiency than that of Comparative Example A2 in which the mesoporous silica particles were not mixed. The organic EL element 1 of Example A1 had a lower refractive index of the light-emitting layer 43 and higher external quantum efficiency than that of Comparative Example A1 using the mesoporous silica particles in which the periphery of the core particles were not covered with silica.

### Antireflective Film

### Example B1

An isopropanol dispersion of the mesoporous silica particles prepared in Example 1 was mixed with a silica matrix precursor to form a complex which was deposited on a glass substrate to prepare an antireflective film.

A methyl silicate oligomer (MS51 (manufactured by Mitsubishi Chemical Corporation)) was used as a silica matrix precursor. The isopropanol dispersion of the mesoporous silica particles as described above was added to the precursor solution so as to give a mass ratio of mesoporous silica particles/silica (in terms of condensation compound) of 15/85 on the basis of solids, and the resulting mixture was further diluted with isopropanol so as to give to a total solids content of 2.5 mass % to obtain a coating liquid for film formation.

This coating liquid for film formation was applied to a glass substrate with a minimum reflectance of 4.34 using a bar coater and dried at 120° C. for 5 minutes to form a film (antireflective film) having a thickness of about 100 nm.

### Comparative Example B1

An isopropanol dispersion of the mesoporous silica particles prepared in Comparative Example 1 was treated with a silica matrix precursor under the same conditions used in the preparation of the antireflective film of Example B1 to form a complex which was deposited on a glass substrate to prepare a film (antireflective film).

### [Comparison of Antireflective Films]

The films obtained in Example B1 and Comparative Example B1 were measured for a haze rate, reflectance and mechanical strength to evaluate film performance. Evaluation results are shown in the following table. Note that the results of the reflectance of a film in which no mesoporous silica particles are blended and the results of the reflectance of a glass substrate are also collectively shown for purposes of comparison.

### (Reflectance)

Reflectance was measured at wavelengths of 380 to 800 nm using a spectrophotometer (“U-4100” manufactured by Hitachi, Ltd.), and the minimum value in this range was given as the lowest reflectance.

### (Haze)

Haze was measured using a haze meter (“NDH 2000” manufactured by Nippon Denshoku Industries Co., Ltd.).

### (Mechanical Strength)

The surface of the antireflective film was reciprocatingly rubbed 10 times over a width of 5 cm with a #0000 steel wool having a size of 2 cm square under a load of 250 g/cm², and the scratches each having a length of 2 cm or more produced on the antireflective film were counted and rated as “X” when the number of scratches was 6 or more, and “◯” when the number of scratches was 0 to 5.

The results are shown in Table 3.

It has been verified that Example B1 has low reflectance over the entire visible light region, and is excellent in low reflection performance. It has also been verified that Example B1 has a lower haze, lower reflectance and higher surface strength than Comparative Example B1 in which the mesoporous silica particles are blended in the same weight ratio as shown in the following table. These results show that a lower refractive index has been achieved by improving the dispersibility of the mesoporous silica particles within the film and sufficiently holding the mesopores in the antireflective film. The mechanical strength is not reduced despite the larger void volume because the mesoporous silica particles each have a core particle whose periphery is covered with silica.

TABLE 3

| | | Lowest | |
|---|---|---|---|
| | | reflectance | Mechanical |
| | Haze | (%) | strength |
| Glass | 0.05 | 4.34 | ◯ |
| substrate | | | |
| No mesoporous | 0.06 | 3.01 | ◯ |
| silica | | | |
| particles | | | |
| blended | | | |
| Example B1 | 0.12 | 2.50 | ◯ |
| Comparative | 0.45 | 2.63 | X |
| Example B1 | | | |

### REFERENCE SIGNS LIST

A Mesoporous Silica Particles
1 Organic EL Element
2 Substrate
3 First Electrode
4 Organic Layer
43 Light-emitting Layer
5 Second Electrode

1. Mesoporous silica particles each comprising a core particle comprising first mesopores, wherein a periphery of the core particle is covered with silica.

2. The mesoporous silica particles according to claim 1, wherein second mesopores, smaller than the first mesopores, are provided in a silica-covered part formed by the silica covering.

3. A method for producing mesoporous silica particles comprising: a surfactant complex silica particle preparation step of mixing a surfactant, water, an alkali, a hydrophobic part-containing additive and a silica source to thereby prepare surfactant complex silica particles, said hydrophobic part-containing additive including a hydrophobic part for increasing a volume of micelles to be formed by the surfactant; and a silica covering step of adding the silica source to the surfactant complex silica particles to thereby cover a periphery of each core particle with silica.

4. The method for producing mesoporous silica particles according to claim 3, wherein the silica covering step comprises adding the silica source and the surfactant to thereby cover the surface with silica complexed with the surfactant.

5. A mesoporous silica particle-containing molded article, the molded article comprising the mesoporous silica particles according to claim 1 in a matrix-forming material.

6. A mesoporous silica particle-containing molded article, the molded article comprising the mesoporous silica particles according to claim 2 in a matrix-forming material.
